(19) United States
(12) Patent Application Publication
(10) Pub. No.: US 2013/0005133 A1
(43) Pub. Date: Jan. 3, 2013

(54) METHOD OF MANUFACTURING A SEMICONDUCTOR DEVICE

(75) Inventors: JUNG-CHAN LEE, SUWON-SI (KR); DAE-YOUNG KWAK, SEONGNAM-SI (KR); SEUNG-JAE LEE, HWASEONG-SI (KR); JAE-SUNG HUR, HWASEONG-SI (KR); SANG-BOM KANG, SEOUL (KR); BYUNG-SUK JUNG, SEOUL (KR); Zulkarnain, Yongin-si (KR)

(73) Assignee: SAMSUNG ELECTRONICS CO., LTD., SUWON-SI (KR)

(21) Appl. No.: 13/523,928

(22) Filed: Jun. 15, 2012

(30) Foreign Application Priority Data
Jun. 28, 2011 (KR) 10-2011-0063089

(51) Int. Cl. H01L 21/283

(52) U.S. Cl. 438/595; 257/E21.19

(57) ABSTRACT

A method of manufacturing a semiconductor device can uniformly form a metal gate irrespective of gate pattern density. The method includes forming an interlayer dielectric layer having a trench on a substrate, forming a metal layer having first, second and third sections extending along the sides of the trench, the bottom of the trench and on the interlayer dielectric layer, respectively, forming a sacrificial layer pattern exposing an upper part of the first section of the metal layer, forming a spacer pattern on the exposed part of the first section of the metal layer, and forming a first gate metal layer by etching the first section of the metal layer using the sacrificial layer pattern and the spacer pattern as masks.

### PRIORITY STATEMENT

This application claims priority from Korean Patent Application No. 10-2011-0063089 filed on Jun. 28, 2011 in the Korean Intellectual Property Office, and all the benefits accruing therefrom under 35 U.S.C. 119, the contents of which are herein incorporated by reference in their entirety.

### BACKGROUND

1. Field

The inventive concept relates to the manufacturing of semiconductor devices. In particular, the inventive concept relates to the fabricating of gate electrodes of transistors.

2. Description of the Related Art

Semiconductor devices are becoming more densely integrated. To this end, various patterns constituting semiconductor devices are being gradually scaled down. In particular, the widths of gates of transistors are being reduced. More specifically, non-memory and logic devices require high performance transistors capable of rapidly operating at a low voltage. To this end, it is necessary to provide such transistors with relatively narrow gates or gate electrodes. In the past, the gate electrodes of transistors were predominantly formed of lines of polysilicon using a photolithographic process. However, the photolithography process imposes limits on how small the line width of a gate electrode may be. Thus, in recent years, gate electrodes are being formed of metal instead of polysilicon.

### SUMMARY

According to an aspect of the present invention, there is provided a method of manufacturing a semiconductor device in which an interlayer dielectric layer having at least one trench therein is formed on a substrate, a metal layer is subsequently formed on the substrate such that the metal layer has a first section extending along sides of the trench, a second section extending along the bottom of the trench and a third section extending along an upper surface of the interlayer dielectric layer, then a sacrificial layer pattern is formed such that it fills only a lower part of the trench and exposes an upper part of the first section of the metal layer in the trench, a spacer pattern is then formed to cover the surface of the exposed upper part of the first section of the metal layer in the trench, and then a first gate metal layer is formed at the lower part of the trench by etching the metal layer using the sacrificial layer pattern and the spacer pattern together as an etch mask.

According to another aspect of the present invention, there is provided a method of manufacturing a semiconductor device in which a substrate is provided, an interlayer dielectric layer is formed having at least one first trench therein on one region of the substrate and at least one second trench therein on another region on the substrate, a mask layer is formed to cover said another region of the substrate, a metal layer is formed in each first trench such that the metal layer has a first section extending along the sides of each first trench and a second section extending along the bottom of each first trench, a sacrificial layer pattern is then formed such that it fills only a lower part of each first trench and exposes an upper part of the first section of the metal layer in the first trench, a spacer pattern is formed to cover the surface of the exposed upper part of the first section of the metal layer in each said first trench, a first gate metal layer is then formed at the lower part of each said first trench by etching the metal layer using the sacrificial layer and spacer patterns together as an etch mask, the mask layer is removed, and subsequently a second gate metal layer is formed to fill what remains of each first trench and fill each second trench.

According to still another aspect of the present invention, there is provided a method of manufacturing a semiconductor device in which an interlayer dielectric layer having first and second trenches therein is formed on a substrate, subsequently a metal layer is formed on the substrate conforming to the underlying topography of an intermediate structure that includes the interlayer dielectric layer and the first and second trenches such that the metal layer extends along surfaces delimiting the sides and bottoms of the first and second trenches, subsequently a sacrificial layer pattern is formed on the substrate by a process that results in the filling of the first trench with sacrificial material to a first level and the filling of the second trench with sacrificial material to a second level below the first level such that the sacrificial layer pattern exposes more of the metal layer in the second trench than in the first trench, a spacer pattern is then formed to cover those parts of the metal layer exposed by the sacrificial layer pattern, and a first gate metal layer is then formed at the lower part of each of the first and second trenches by etching the metal layer using the sacrificial layer and spacer patterns together as an etch mask.

### BRIEF DESCRIPTION OF THE DRAWINGS

The inventive concept will become more apparent from the following detailed description of the preferred embodiments thereof made with reference to the attached drawings in which:

FIG. 1 is a flowchart of a method of manufacturing a semiconductor device according to the inventive concept;

FIGS. 2 to 12 are sectional views of intermediate structures formed during the course of a first embodiment of manufacturing a semiconductor device according to the inventive concept;

FIGS. 13 and 14 are sectional views of intermediate structures formed during the course of another example of the first embodiment of a method of manufacturing a semiconductor device according to the inventive concept;

FIGS. 15 to 22 are sectional views of intermediate structures formed during in the course of a second embodiment of a method of manufacturing a semiconductor device according to the inventive concept;

FIGS. 23 and 24 are sectional views of intermediate structures during the course of a method in which a spacer pattern is not formed prior to the forming of first gate metal layers in trenches having different widths, for use in illustrating advantages of the second embodiment;

FIGS. 25 to 27 are sectional views of intermediate structures formed during another example of the second embodiment of a method of manufacturing a semiconductor device according to the inventive concept; and

FIGS. 28 to 30 are sectional views of intermediate structures formed during still another example of the second embodiment of a method of manufacturing a semiconductor device according to the inventive concept.

### DETAILED DESCRIPTION OF THE PREFERRED EMBODIMENTS

Various embodiments and examples of embodiments of the inventive concept will be described more fully hereinafter with reference to the accompanying drawings. In the drawings, the sizes and relative sizes and shapes of elements, layers and regions shown in section may be exaggerated for clarity. In particular, the cross-sectional illustrations of the semiconductor devices and intermediate structures fabricated during the course of their manufacture are schematic. Also, like numerals are used to designate like elements throughout the drawings.

It will also be understood that when an element or layer in question is referred to as being “on” or “over” another element or layer, the element or layer in question can be directly on the other element or layer or intervening elements or layers may be present.

Furthermore, the terms first, second, third etc. are used herein to describe various elements, layers or regions. However, these elements, layers, and/or regions are not limited by these terms. Rather, these terms are only used to distinguish one element, layer or region from another.

Other terminology used herein for the purpose of describing particular examples or embodiments of the inventive concept is to be taken in context. For example, the terms “comprises” or “comprising” when used in this specification specifies the presence of stated features or processes but does not preclude the presence or additional features or processes. Furthermore, the meaning of the term “layer” is to be taken in context especially with reference to the drawings. For instance, the term “layer” may be used at times to denote a contiguous layer or merely a segment or discrete section of a non-contiguous layer of material. The term “trench” may be used to denote an elongated segment or discrete section of a contiguous or non-contiguous opening. The term “pattern” may also be used to refer to one of a series of repeating features or the entire series of repeating features.

A method of manufacturing a semiconductor device according to the inventive concept will now be described with reference to FIGS. 1 to 12.

Referring first to FIGS. 1 to 3, an interlayer dielectric layer 114 defining a trench 115 is formed on a substrate 100 (S1010).

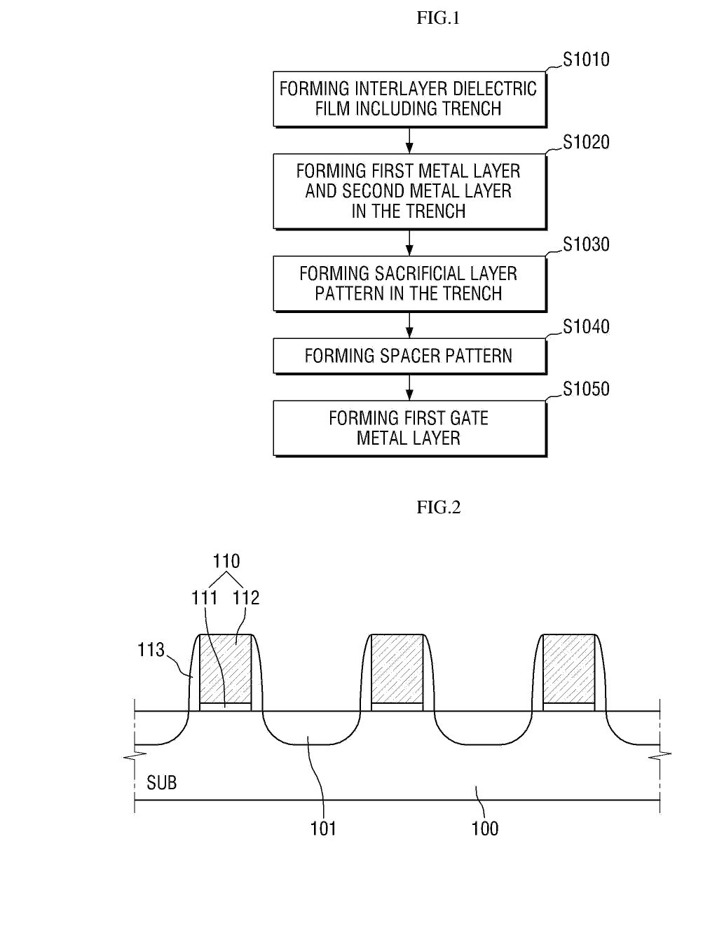

For example, referring to FIG. 2, and although not shown, a device isolation region may be formed on a substrate 100 for defining an active region. The device isolation region may be a field oxide (FOX) layer formed using a local oxidation of silicon (LOCOS) or shallow trench isolation (STI) method. The substrate 100 may be a rigid substrate such as a silicon substrate, a silicon on insulator (SOI) substrate, a gallium arsenide substrate, a silicon germanium substrate, a ceramic substrate, a quartz substrate, or a glass substrate (in the case in which the device is to be used by a display). Alternatively, the substrate 100 may be a flexible substrate of plastic such as polymethylmethacrylate, polycarbonate, polyethersulfone, polyimide, polyethylene terephthalate, or polyethylene naphthalate.

Next, an insulation layer and a conductive layer are sequentially formed on the substrate 100. The insulation layer may be a silicon oxide layer formed by thermal oxidation, chemical vapor deposition (CVD), physical vapor deposition (PVD) or atomic layer deposition (ALD). The conductive layer may be formed of polysilicon. Then a photoresist pattern (also not shown) is formed on the conductive layer, and the insulation layer and the conductive layer are then etched using the photoresist pattern as a mask, and the photoresist pattern is removed. As a result, a dummy gate pattern 110 including a dummy gate insulation layer 111 of silicon oxide, and a dummy gate electrode 112 of polysilicon, for example, are formed.

Referring to FIG. 2, gate spacers 113 are formed on sidewalls of the dummy gate pattern 110. For example, an insulating layer is conformally formed so as to conform to the topography of the substrate 100 and dummy gate pattern 110, and anisotrophically etched to form the gate spacers 113. The insulating layer and hence, the gate spacers 113, is preferably formed of a material having a high etching selectivity with respect to the dummy gate pattern 110. For example, the insulating layer for forming the gate spacers 113 is a silicon nitride layer.

Subsequently, the substrate 100 is doped with impurities using the dummy gate pattern 110 and the gate spacers 113 as a mask, thereby forming source/drain regions 101.

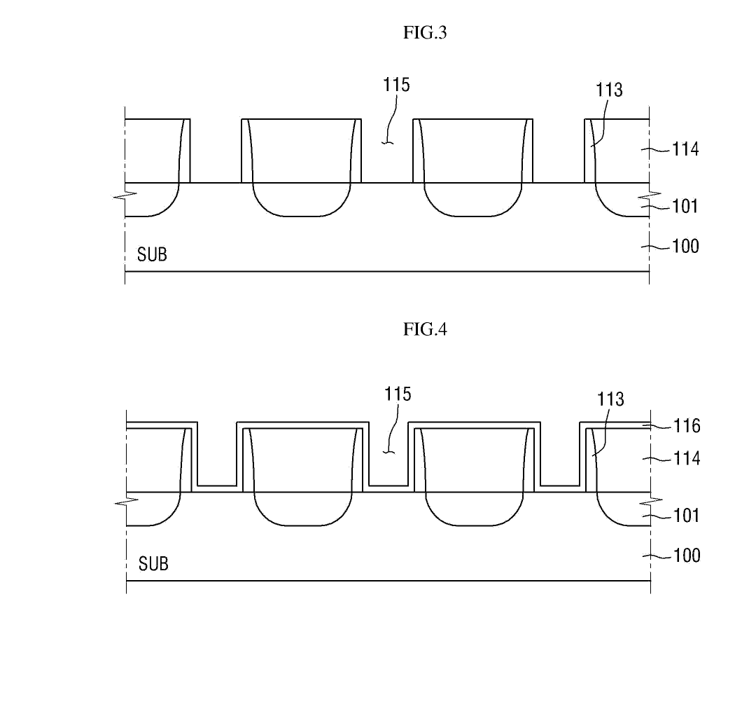

Next, Referring again to FIG. 3, an interlayer dielectric layer 114 is formed on the substrate 100. For example, the interlayer dielectric layer 114 is formed by depositing a silicon oxide layer on the dummy gate pattern 110 using CVD, PVD or ALD. The silicon oxide layer may be formed to such a thickness that the top surface thereof is located at a level above that of the top surface of the dummy gate pattern 110.

Next, the dummy gate pattern 110 is removed to form a trench 115. More specifically, in the example described above, the insulating layer is planarized until the top surface of the dummy gate pattern 110 is exposed. The planarization process may be a chemical mechanical polishing (CMP) or an etch back process. Then the dummy gate pattern 110 is selectively removed by reactive ion etching, for example, to form trench 115. In this case, trench 115 exposes the top surface of the substrate 100. Alternatively, only the dummy gate electrode 112 is removed, such that the dummy gate dielectric layer 111 remains on the substrate.

Referring now to FIG. 4, a gate insulation layer 116 is formed on the surfaces delimiting the bottom and sides of the trench 115 and on the top surface of the interlayer dielectric layer 114.

In the example of this embodiment in which the dummy gate pattern 110 is removed, the gate insulation layer 116 may be formed by depositing silicon oxide, high-k dielectric material (material whose dielectric constant is greater than that silicon oxide), or a mixture thereof on the substrate 100 using CVD, PVD or ALD. Examples of the high-k dielectric material include (i.e, the high-k dielectric material may be but is not limited to) at least one material selected from the group consisting of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In the example of this embodiment in which the dummy gate dielectric layer 111 is not removed, the dummy gate insulation layer 111 may serve as the gate insulation layer 116.

Referring to FIGS. 1, 4 and 5, a first metal layer and a second metal segment are then formed in the trench 115 along the sides and bottom of the trench 115, respectively (S1020).

For example, referring to FIG. 5, a metal layer 121 having first, second and third sections 121a, 121b and 121c is formed on the gate insulation layer 116 by CVD, PVD, ALD or sputtering. In this respect, the first metal 121a extends along the sides of the trench 115, the second section 121b extends along the bottom of the trench 115 and the third section 121c extends along the interlayer dielectric layer 114.

The metal layer 121 is formed of conductive material having a work function dictated by the type of transistor to be formed. For example, if the transistor is to be an NMOS transistor, the metal layer 121 is formed of conductive material whose work function is closer to the conduction band of the semiconductor material (e.g., silicon) of the substrate 100 than to the valence band. In contrast, if the transistor is to be a PMOS transistor, the metal layer 121 is formed of conductive material whose work function is closer to the valence band than to the conduction band of the semiconductor material (e.g., silicon) of the substrate. In this embodiment, the metal layer 121 is formed of at least one material selected from the group consisting of nickel, ruthenium, ruthenium oxide, molybdenum, molybdenum nitride, molybdenum silicide, tantalum, tantalum nitride, tantalum silicide, tungsten, titanium, titanium nitride, and n- and p-type doped polysilicon. Thus, the metal layer 121 may be a mono-layer or may be a laminate. Regardless, the inventive concept is not limited to forming the metal layer 121 from any of the above-noted materials.

Referring to FIGS. 1, 6 and 7, a sacrificial layer pattern 131 exposing a side surface of the first section 121a of the metal layer 121 is formed in the trench 115 (S1030).

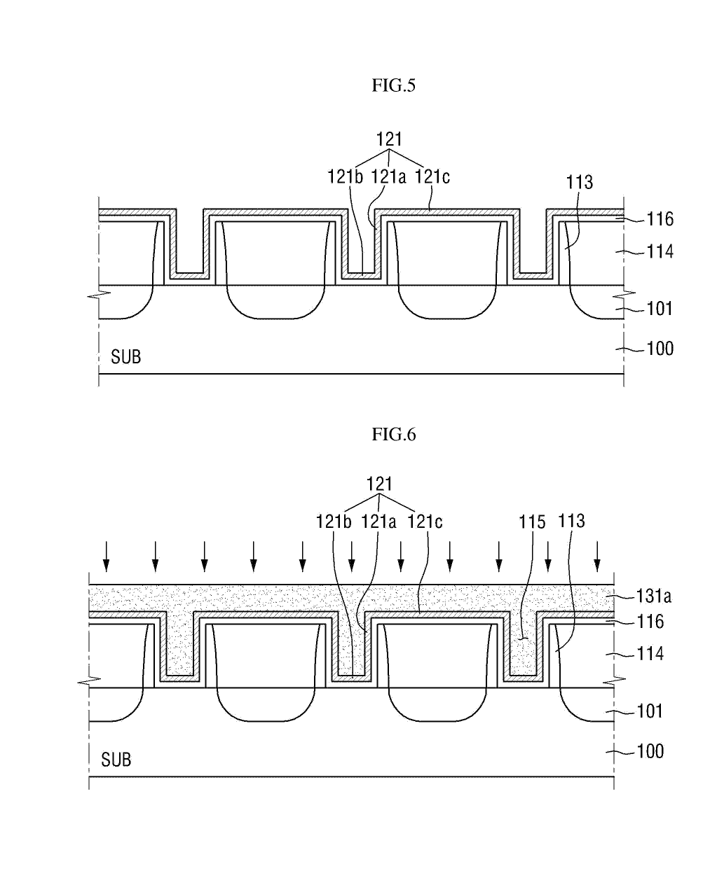

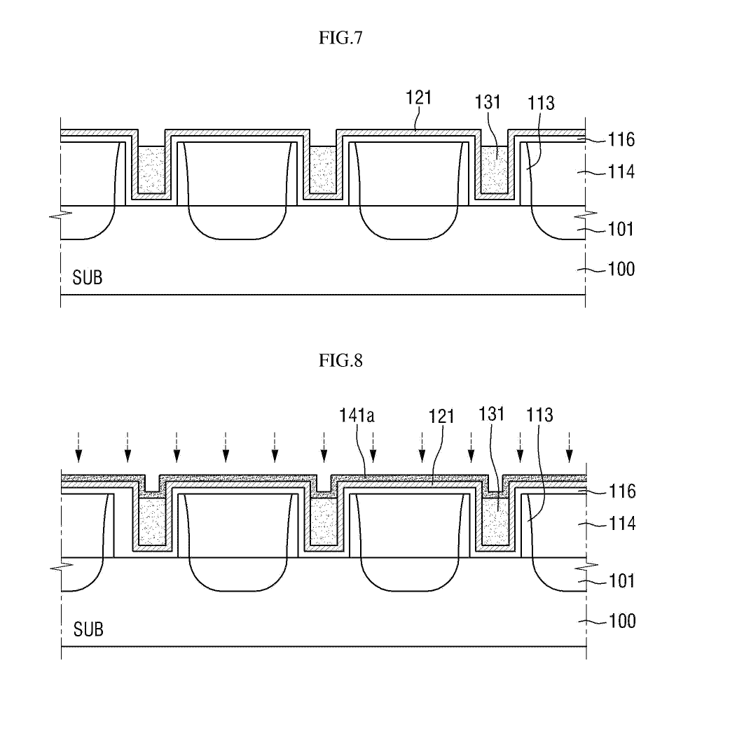

For example, referring to FIG. 6, a sacrificial layer 131a is formed on the substrate 100 to such a thickness as to fill the trench 115. The sacrificial layer 131a is preferably formed of material having a high etch selectivity with respect to the metal layer 121. In particular, the sacrificial layer 131a is preferably formed of material having an etch selectivity of 3:1 or higher with respect to the metal layer 121. The sacrificial layer 131a may include siloxane. For example, the sacrificial layer 131a is formed of an organosiloxane polymer such as polydimethylsiloxane. In this case, the sacrificial layer 131a may be formed by coating the metal layer 121 with a siloxane-based polymer.

Referring to FIGS. 6 and 7, the sacrificial layer 131a is etched by, for example, an etch back process and to such an extent that the top surface thereof is located at a level beneath the level of the top surface of the third section 121c of the metal layer 121 on the interlayer dielectric layer 114. The resulting sacrificial layer pattern 131 exposes an upper part of the surfaces of the first section 121a of the metal layer 121 extending along the sides of the trench 115.

Referring to FIGS. 1, 8 and 9, a spacer pattern 141 is formed on the exposed surfaces of the first metal layer (i.e., on the upper part of the first section 121a of the metal layer 121) (S1040).

For example, referring to FIG. 8, a spacer layer 141a is formed on the top surface of the sacrificial layer pattern 131, the exposed surfaces of the first section layer 121a of the metal layer 121 and the top surface of the third layer 121c of the metal layer 121. The spacer layer 141a may be formed by CVD, PVD, or ALD. In addition, the spacer layer 141a may be formed of at least one material selected from the group consisting of silicon oxide, silicon nitride, polysilicon and carbon-based materials. Carbon-based materials refer to carbon or carbon complexes. For example, the spacer layer 141a is formed by depositing a hydrocarbon (e.g., C₃H₆) in a plasma state on the surfaces noted above, resulting in a carbon-based material that is part diamond and part graphite.

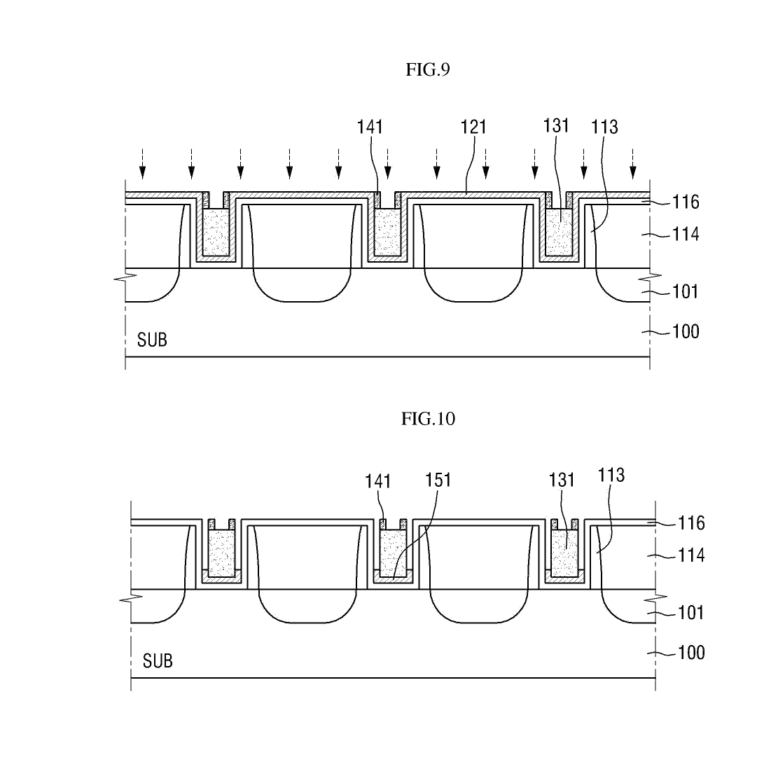

Referring to FIG. 9, the spacer layer 141a is then selectively etched to remove those parts thereof that were formed on the top surface of the sacrificial layer pattern 131 and on the top surface of the third section 121c of the metal layer 121. The portion of spacer layer 141a remaining along the first section 121a of the metal layer 121 constitutes the spacer pattern 141. Thus, the upper part of the first section 121a of the metal layer 121 is protected by the spacer pattern 141.

Referring to FIGS. 1, 10 and 11, a first gate metal layer 151 is formed by etching the first and third sections 121a and 121c of the metal layer 121 using the sacrificial layer pattern 131 and the spacer pattern 141 as masks (S1050).

The first and third sections 121a and 121c of the metal layer 121 may be etched using an etching solution of hydrogen peroxide (H₂O₂), deionized water and ammonia, or an etching solution consisting of hydrogen peroxide (H₂O₂). FIG. 10 illustrates a case in which the top surface of the etched first section 121a of metal layer 121 remains at a level above that of the top surface of the second section 121b of the metal layer 121 extending along the bottom surface of the trench 115. However, the first section 121a of metal layer 121 may be etched until its top surface becomes flush with that of the top surface of the second section 121b (as shown in FIG. 2). As another alternative, the first section 121a of metal layer 121 may be etched completely such that the side surfaces of the gate insulation layer 116 are entirely exposed.

Referring to FIG. 11, the sacrificial layer pattern 131 and the spacer pattern 141 are removed by an etching process using an etching solution or etching gas that does not contain fluorine, i.e., without using hydrogen fluoride (HF) because HF would etch or damage the first gate metal layer 151 and the gate insulation layer 116, affecting the physical properties of the first gate metal layer 151 and the gate insulation layer 116 and thereby allowing for increased leakage current. In the present embodiment, the sacrificial layer pattern 131 may be removed without using an etchant containing fluorine because the sacrificial layer pattern 131 comprises siloxane. Thus, in this embodiment, the sacrificial layer pattern 131 and the spacer pattern 141 may be removed using an etching solution of alkylammonium hydroxide.

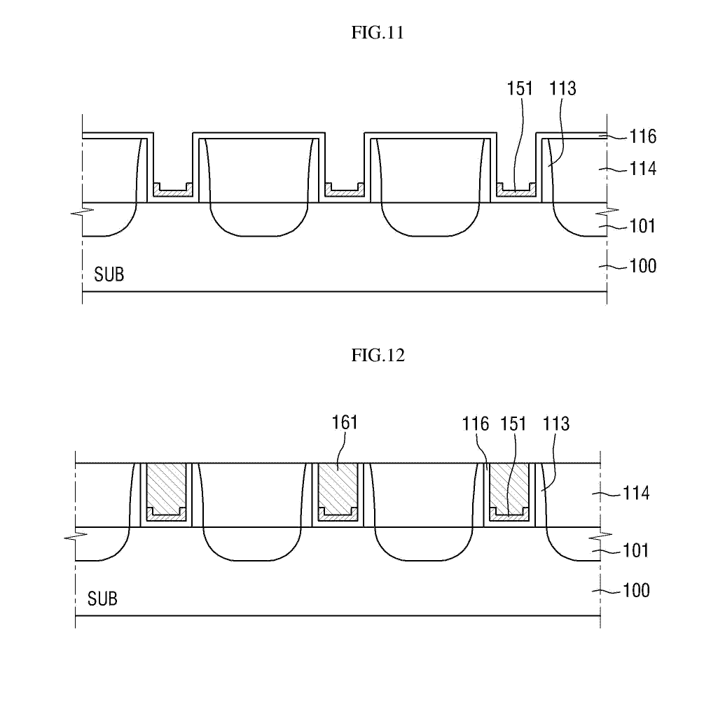

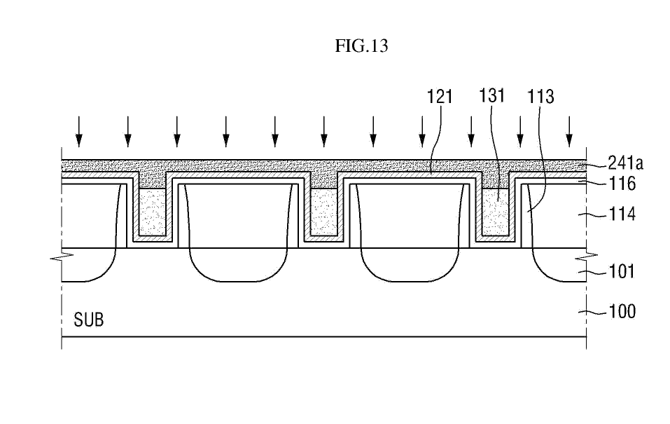

Next, Referring to FIG. 12, a second gate metal layer 161 is formed to such a thickness as to fill the trench 115. For example, a conductive layer is formed to such a thickness as to fill the trench 115 and cover the interlayer dielectric layer 114. The conductive layer may be formed by CVD, PVD, ALD or sputtering of at least one material selected from the group consisting of aluminum, tungsten, molybdenum, titanium, tantalum and copper. However, the inventive concept is not limited to the forming of the conductive layer (i.e., the second gate metal layer 161) from such a material or materials. In any case, the conductive layer is then planarized until a top surface of the interlayer dielectric layer 114 is exposed. The planarization process may be a CMP process.

In the method of manufacturing a semiconductor device according to the inventive concept as described above, the first gate metal layer 151 is formed by removing that part of the first metal layer 121 formed on the sides of the trench 115. Therefore, the second gate metal layer 161 filling the trench 115 includes an extra volume of conductive material corresponding to the volume of the part of the metal layer 121 removed from the sides of the trench 115. Accordingly, not only is the deposition of the material used to form second gate metal layer 161 facilitated, but the resulting gate has a relatively low resistance.

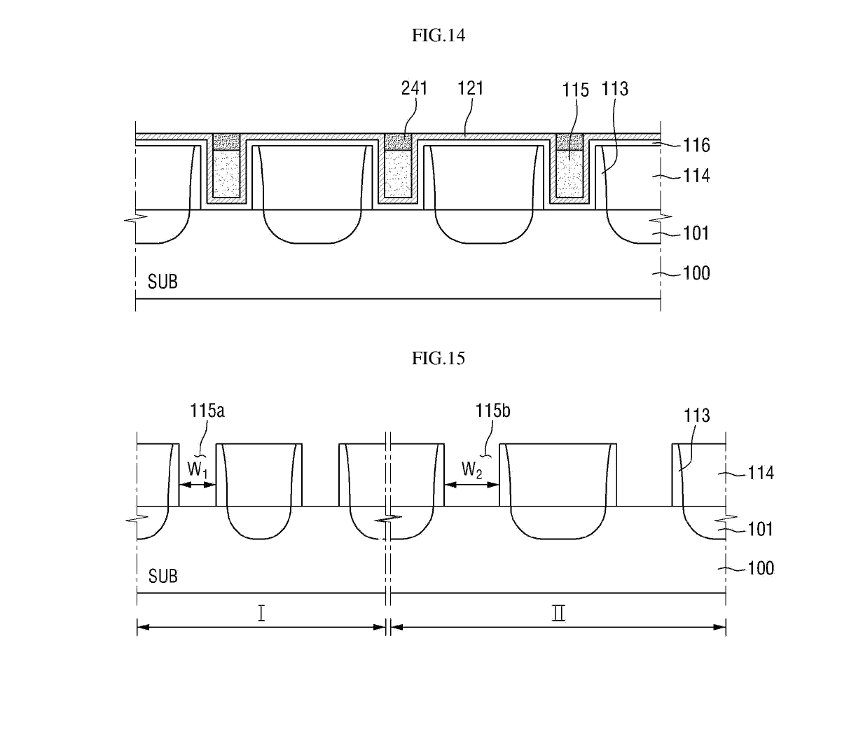

Hereinafter, another example of the first embodiment of a method of manufacturing a semiconductor device according to the inventive concept will be described with reference to FIGS. 13 and 14. This example differs from that of the first example only with respect to the forming of the spacer pattern and thus, mainly only the forming of the spacer pattern will be described in detail for the sake of brevity.

That is, processes similar to those described with reference to FIGS. 3-7 are performed.

Referring to FIG. 13, next, a spacer layer 241a is formed to such a thickness as to fill trench 115 and cover interlayer dielectric layer 114.

Referring to FIG. 14, a spacer pattern 241 is then formed by planarizing the spacer layer 241a until a top surface of the third section 121c of the metal layer 121, i.e., that part of the metal layer 121 extending along the interlayer dielectric layer 114, is exposed. The planarization process may be a CMP process.

Next, processes similar to those described above with reference to FIGS. 10-12 are preformed to form first gate metal layer 151 and second gate metal layer 161 in trench 115.

A second embodiment of a method for manufacturing a semiconductor device according to the inventive concept will now be described with reference to FIGS. 15 to 22.

Referring to FIG. 15, an interlayer dielectric layer 114 having a first trench 115a having a first width W₁ and a second trench 115b having a second width W₂ different from the first width W₁ is formed on a substrate 100. FIG. 15 illustrates that the second trench 115b is wider than the first trench 115a. i.e., that the width W₂ is greater than the width W₁. The first trench 115a is located in a first region I of the device and the second trench 115b is located in a second region II of the device.

Gate spacers 113 are then formed along the sides of the first trench 115a and the second trench 115b.

The first trench 115a, the second trench 115b and the gate spacers 113 are formed in a manner similar to that described above in connection with the first embodiment.

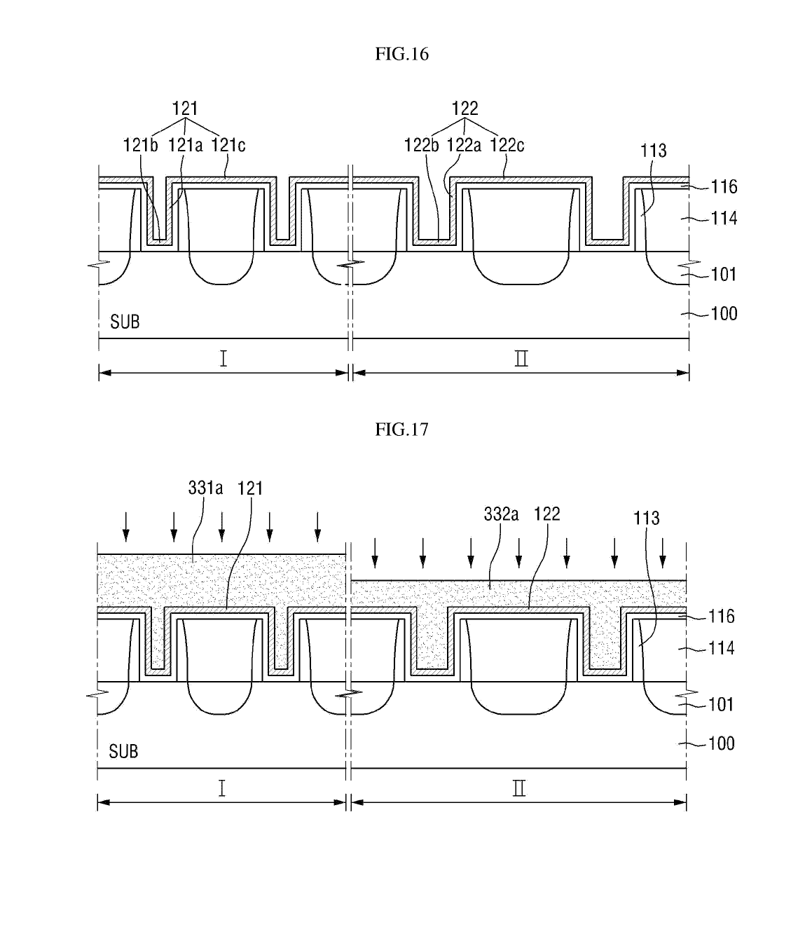

Referring to FIG. 16, a metal layer 121, 122 is conformally formed in the first region I and the second region II of the device, respectively. The metal layer 121,122 has first sections 121a and 122a extending along the sides of the first trench 115a and along the sides of the second trench 115b, respectively, second sections 121b and 122b extending along the bottom of the first trench 115a and along the bottom of the second trench 115b, respectively, and third sections 121c and 122c extending on top surfaces of the interlayer dielectric layer 114. That is to say, the metal layer 121,122 conforms to the topography of the structure constituted by the interlayer dielectric layer 114 in which the first trench 115a and the second trench 115b are provided.

Referring to FIG. 17, first sacrificial layer 331a and second sacrificial layer 332a are formed to such a thickness as to fill the first trench 115a and the second trench 115b and cover the interlayer dielectric layer 114. The first sacrificial layer 331a is formed on the substrate 100 in the first region I, and the second sacrificial layer 332a is formed on the substrate 100 in the second region II.

Furthermore, the first sacrificial layer 331a and the second sacrificial layer 332a comprise siloxane. More specifically, the first sacrificial layer 331a and the second sacrificial layer 332a are formed by coating the metal layer 121, 122 with material including a siloxane-based polymer.

As a result, the top surface of the second sacrificial layer 332a filling the second trench 115b is disposed at a level beneath that of the top surface of the first sacrificial layer 331a because width W₁ of the first trench 115a formed in the first region I is smaller than the width W₂ of the second trench 115b formed in the second region II. In addition, the pattern density of the interlayer dielectric pattern 114 and trenches may also be responsible for the fact that the levels of the top surfaces of the first and second sacrificial layers become different from each other when the metal layer 121, 122 is coated with the material used to form the first and second sacrificial layers 331a and 332a.

Referring to FIG. 18, the first sacrificial layer 331a and the second sacrificial layer 332a are etched to form first sacrificial layer pattern 331 and second sacrificial layer pattern 332 exposing surfaces of the first sections 121a and 122a of the portions of the metal layer 121,122 disposed in the first region I and the second region II, respectively. The first sacrificial layer 331a and the second sacrificial layer 332a may be etched at the same rate using an etch back process. If the first sacrificial layer 331a and the second sacrificial layer 332a are etched at the same etch rate, the first sacrificial layer pattern 331 has a greater than the second sacrificial layer pattern 332 because the top surface of the first sacrificial layer 331a was disposed above the level of the top surface of the second sacrificial layer 332a. In addition, an etching solution may have difficulty in permeating the first trench 115a because the width W₁ of the first trench 115a is relatively small, thereby also contributing to the fact that a relatively small amount of the first sacrificial layer 331a is etched in the first trench 115a. For these reasons, more of the surface of the first section 122a of the metal layer 122 in the second region II is exposed than the surface of the first section 121a of the metal layer 121 in the first region I.

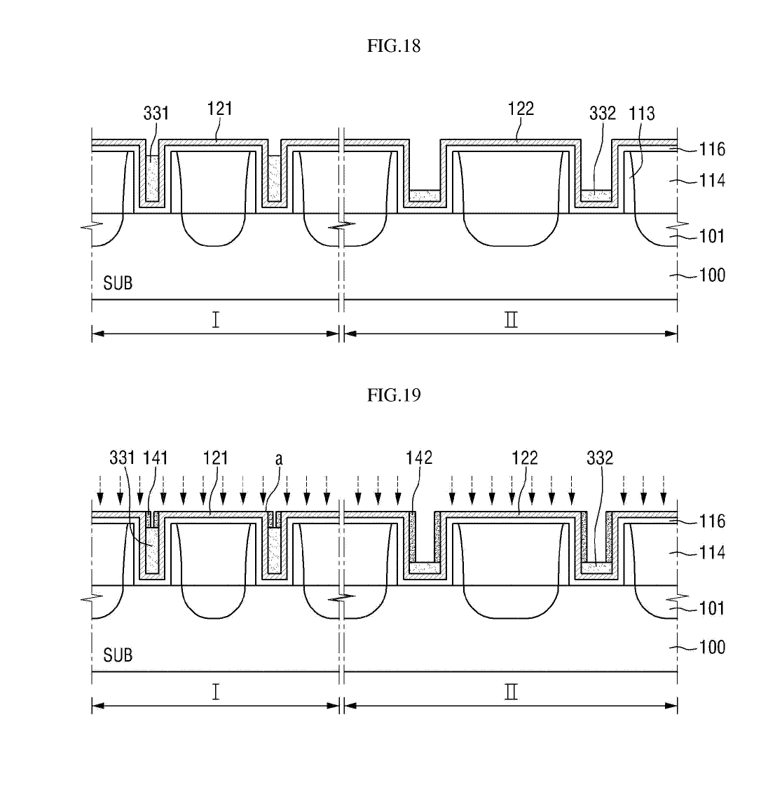

Referring to FIG. 19, a first spacer pattern 141 and a second spacer pattern 142 covering the exposed surfaces of first sections 121a and 122a of the metal layer 121, 122 are formed in the first trench 115a of the first region I and the second trench 115b of the second region II, respectively. The first spacer pattern 141 and the second spacer pattern 142 are formed on the first sacrificial layer pattern 331 and the second sacrificial layer pattern 332, respectively, to the same level as the top surfaces of the third sections 121c and 122c of the metal layer 121, 122. In this respect, the first spacer pattern 141 and the second spacer pattern 142 are formed in a manner similar to that described above in connection with the first embodiment.

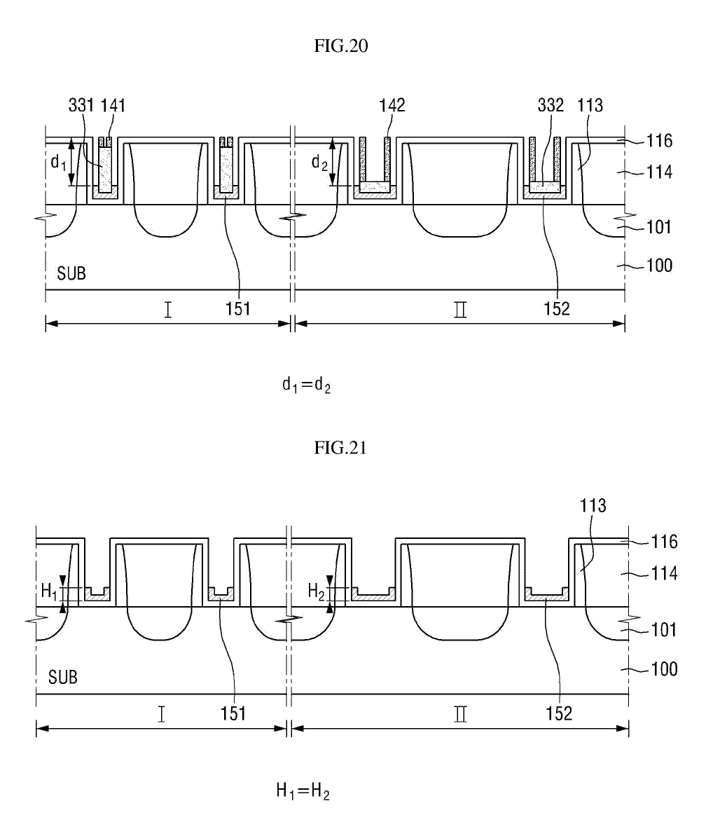

Referring to FIG. 20, the section 121a and the third section 121c of the metal layer 121 in the first region I are etched using the first sacrificial layer pattern 331 and the first spacer pattern 141 as masks, and the first section 122a and the third section 122c of the metal layer 122 in the second region II are etched using the second sacrificial layer pattern 332 and the second spacer pattern 142 as masks. In this process, the etching begins at the top surfaces ‘a’ of the third 121c of the metal layer 121 in the first region I and the third section 122c of the metal layer 122 in the second region II and proceeds towards the substrate 100. Also, the first sections 121a and 122a of the metal layer 121, 122 are etched at the same etch rate. Thus, the depth d₁ to which the first section 121a of the metal layer 121 in the first region I is etched is equal to the depth d₂ to which the first section 122a of the metal layer 122 in the second region II is etched.

Referring to FIG. 21, first gate metal layers 151 and 152 are formed in the first region I and the second region II by removing the first sacrificial layer pattern 331 and the first spacer pattern 141 from the first region I and the second sacrificial layer pattern 332 and the second spacer pattern 142 from the second region II, respectively. At this time, the height H₁ of the first gate metal layer 151 of the first region I is equal to the height H₂ of the first gate metal layer 152 of the second region II.

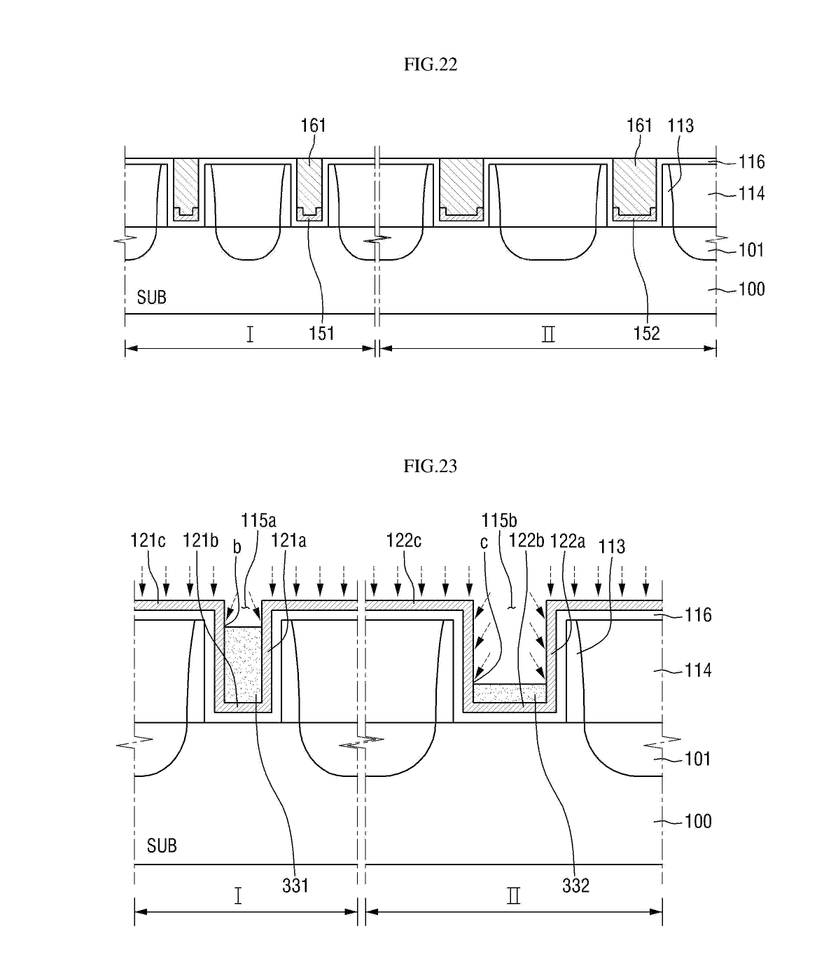

Referring to FIG. 22, a second gate metal layer 161 is formed in the first region I and the second region II to fill the first trench 115a and the second trench 115b. The second gate metal layer 161 is formed in a manner similar to that described above in connection with the first embodiment.

In the above-described second embodiment of a method of manufacturing a semiconductor device according to the inventive concept, the first trench 115a and second trench 115b have different widths (and the density pattern is) such that the heights of sacrificial layer patterns formed in the first and second trenches 115a and 115b are different from each other. However, the forming of the spacer patterns allows the sections of the metal layer disposed along the sides of the first and second trenches 115a and 115b to be etched at the same etch rate beginning at the tops thereof. Consequently, the first gate metal layers can be formed to the same height in the first and second trenches 115a and 115b. That is, gate metal layers having the same height can be formed irrespective of the pattern density and gate widths, thereby facilitating the manufacturing process.

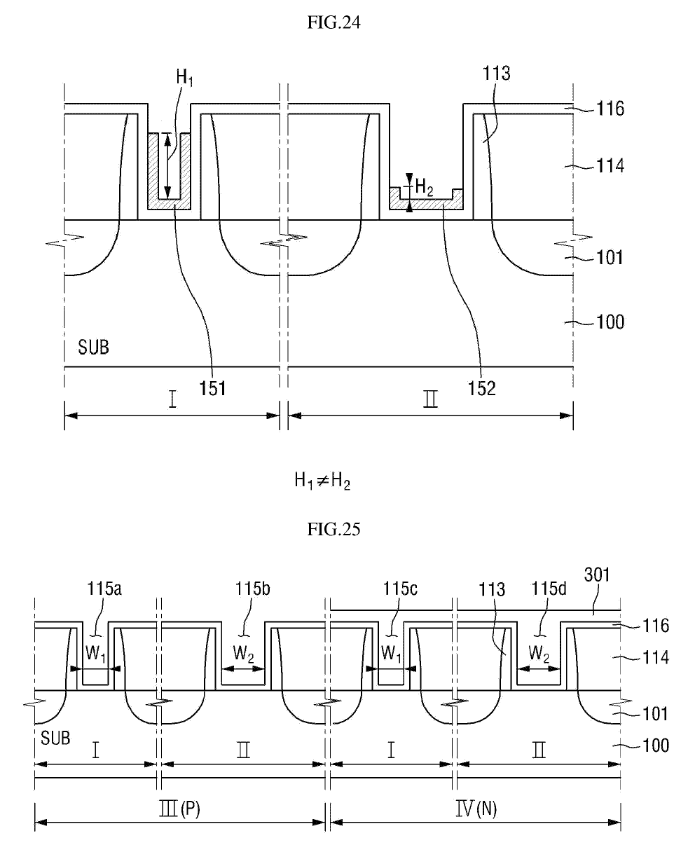

The advantages of the above-described second embodiment of a method of manufacturing a semiconductor device according to the inventive concept will now be described with reference to a comparative example of a similar method, as shown in FIGS. 23 and 24, but in which a spacer pattern is not formed in the trenches.

Referring to FIG. 23, similar to what was shown in and described with reference to FIG. 18, the top surface of first sacrificial layer pattern 331 formed in first trench 115a is located a level above that of the top surface of second sacrificial layer pattern 332 formed in second trench 115b. Therefore, (the first section 122a of) the metal layer in the second trench 115b is exposed to a greater extent than (the first section 121a of) the metal layer in the first trench 115a. Thus, with respect to the etching process, the first section 121a of the metal layer in the first trench 115a is etched towards substrate 100 beginning at a location ‘b’, and the first section 122a of the metal layer in the second trench 115b is etched towards the substrate 100 beginning at a location ‘c’ which is beneath the level of the location ‘b’.

Referring to FIG. 24, assuming that the etching process is stopped before the gate insulation layer 116 disposed under the metal layer in the second trench 115b is damaged, the height H₁ of the resulting first gate metal layer 151 in the first relatively narrow trench 115a is greater than the height H₂ of the first gate metal layer 152 in the second trench 115b. Accordingly, the first gate metal layer 151 in the first trench 115a still occupies a relatively good amount of the volume of the first relatively narrow trench 115a, making it difficult to fill the remainder of the first trench 115a with a second gate metal layer in a subsequent process similar to that described above in connection with FIG. 22. On the other hand, as described above in connection with the second embodiment of a method of manufacturing a semiconductor device according to the inventive concept, by forming the spacer patterns, the first gate metal layers can be formed to the same height in the trenches having different widths. Consequently, the height of the first gate metal layer in the relatively narrow trench can be reduced to provide enough space to facilitate the forming of the second gate metal layer in the relatively narrow trench.

Another example of the second embodiment of a method of manufacturing a semiconductor device according to the inventive concept will be described with reference to FIGS. 25 to 27. The steps of this method which are similar to those described above will not be described in detail for the sake of brevity.

Referring to FIG. 25, an interlayer dielectric layer 114 including a plurality of trenches having different widths is formed on a substrate 100 including a PMOS region III and an NMOS region IV. More specifically, a first trench 115a having a first width W₁ and a second trench 115b having a second width W₂ are formed on the PMOS region III of the substrate 100. Likewise, a third trench 115c having a first width W₁ and a fourth trench 115d having a second width W₂ are formed on the NMOS region IV of the substrate 100. A gate insulation layer 116 is formed on the sides and bottoms of the first to fourth trenches 115a, 115b, 115c and 115d and on the top surface of the interlayer dielectric layer 114.

Referring to FIG. 25, a mask layer 301 is then formed on the NMOS region IV of the substrate 100 so as to cover the third trench 115c, the fourth trench 115d and that part of the interlayer dielectric layer 114 extending over the NMOS region IV of the substrate 100. The mask layer 301 may be formed of any material that can protect the NMOS region IV during a subsequent process.

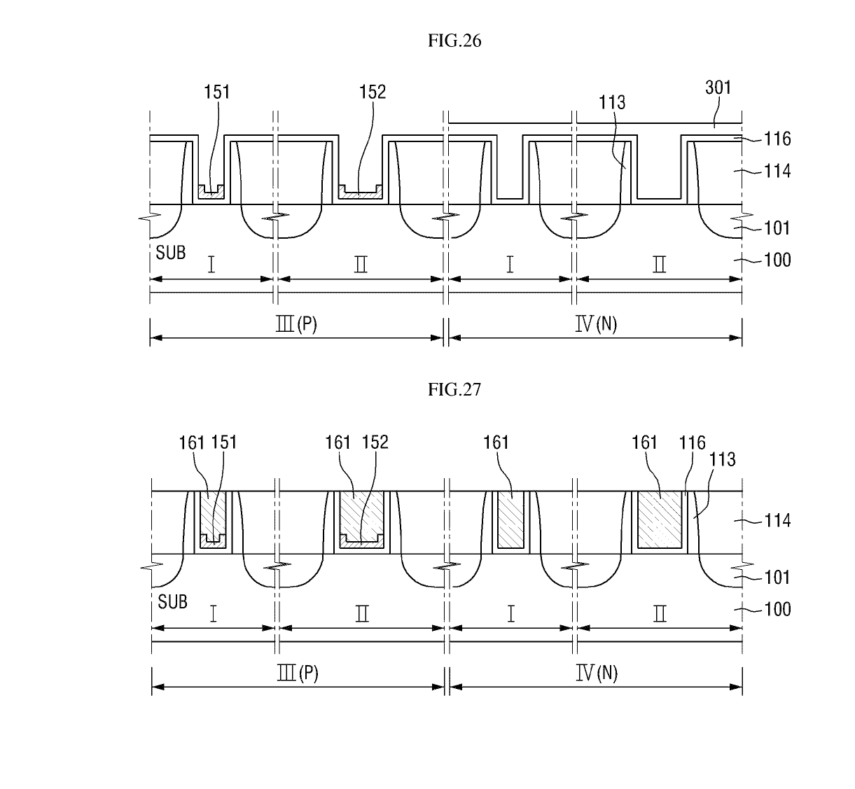

Referring to FIG. 26, first gate metal layers 151 and 152 are formed in the first trench 115a and the second trench 115b on the PMOS region III of the substrate 100 in a manner similar to that described above with reference to FIG. 21. The first gate metal layers 151 and 152 may be formed of, for example, titanium nitride (TiN). In addition, the height of the first gate metal layers 151 and 152 may be designed for based on the work function required by the PMOS transistors to be formed on the PMOS region III of the substrate 100.

Referring to FIG. 27, the mask layer 301 is removed, and a second gate metal layer 161 is formed to such a thickness as to fill the first trench 115a and the second trench 115b on the PMOS region III of the substrate 100 and the third trench 115c and the fourth trench 115d on the NMOS region IV of the substrate 100.

In this example, the first gate metal layers 151 and 152 are formed only on the PMOS region III, i.e., are not formed on the NMOS region IV. Alternatively, the first gate metal layers 151 and 152 may be formed on the NMOS region IV but not on the PMOS region III.

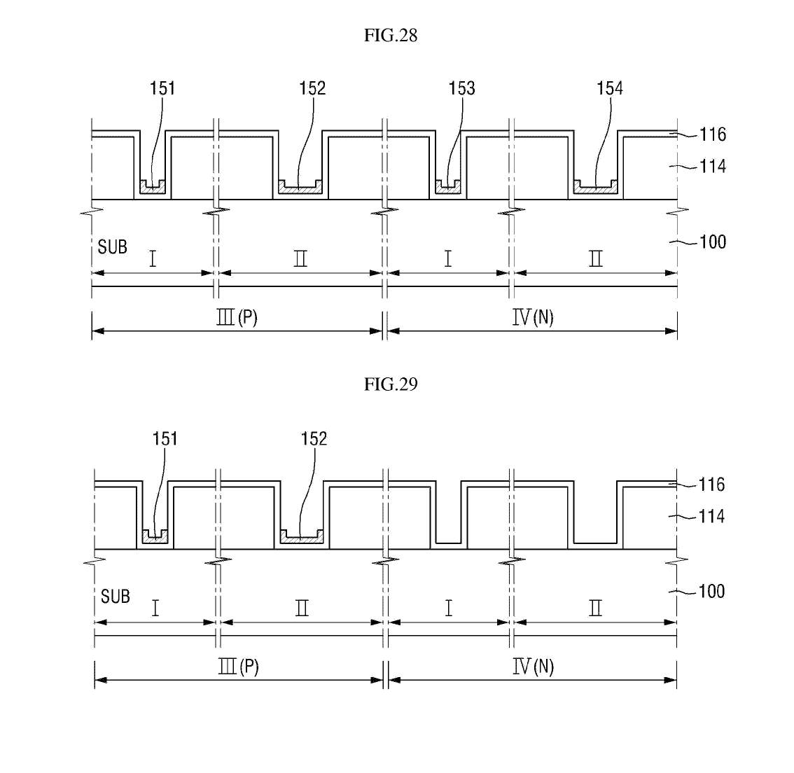

Still another example of the second embodiment of a method of manufacturing a semiconductor device according to the inventive concept will be described with reference to FIGS. 28 to 30. Again, only those aspects of this example which differ from those described above will be described in detail.

Referring to FIG. 28, first gate metal layers 151, 152 are respectively formed in a first trench 115a having a first width W₁ and a second trench 115b having a second width W₂ on the PMOS region III of the substrate 100, and first gate metal layers 153 and 154 are respectively formed in a third trench 115c having the first width W₁ and a fourth trench 115d having the second width W₂ formed on the NMOS region IV of the substrate 100.

Referring to FIG. 29, the first gate metal layers 153 and 154 are then removed from the substrate 100, i.e., from the NMOS region IV. Alternatively, the first gate metal layers 151 and 152 may be removed instead from the PMOS region III.

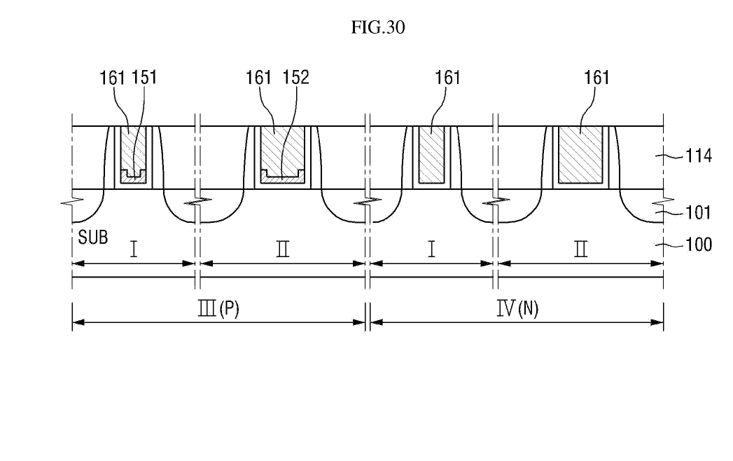

Referring to FIG. 30, a second gate metal layer 161 is then formed to such a thickness as to fill the first to fourth trenches 115a, 115b, 115c and 115d.

In the examples of FIGS. 26 and 27 and of FIGS. 28-30 described above, the first gate metal layer is formed only one of the PMOS region III and the NMOS region IV region of the substrate 100 to provide the transistors formed in that region with a certain work function. In addition, even when trenches having different widths are formed on a PMOS region III and/or an NMOS region IV, first gate metal layers of the same height may be formed in the trenches.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiment and examples described above but by the following claims.

What is claimed is:

1. A method of manufacturing a semiconductor device, the method comprising:
forming an interlayer dielectric layer having at least one trench therein on a substrate;
subsequently forming a metal layer on the substrate such that the metal layer has a first section extending along sides of the trench, a second section extending along the bottom of the trench and a third section extending along an upper surface of the interlayer dielectric layer;
forming a sacrificial layer pattern that fills only a lower part of the trench and exposes an upper part of the first section of the metal layer in the trench;
forming a spacer pattern covering the surface of the exposed upper part of the first section of the metal layer in the trench; and
forming a first gate metal layer at the lower part of the trench by etching the metal layer using the sacrificial layer pattern and the spacer pattern together as an etch mask.

2. The method of claim 1, wherein the forming of an interlayer dielectric layer on the substrate comprises forming an interlayer dielectric layer having a first trench in a first region of the device and a second trench that is wider than the first trench in a second region device, and the first gate metal layer is formed to the same height in the first and second trenches.

3. The method of claim 1, wherein the forming of the sacrificial layer pattern comprises:
coating the substrate, on which the metal layer has been formed, with a sacrificial layer of material comprising siloxane, and
etching the sacrificial layer to expose the upper part of the first section of the metal layer.

4. The method of claim 3, wherein the sacrificial layer is etched using an etchant having an etch selectivity of 3:1 or greater with respect to the metal layer.

5. The method of claim 1, wherein the forming of the spacer pattern comprises:
forming a spacer layer conformally along the exposed upper part of the first section of the metal layer, the sacrificial layer pattern and the interlayer dielectric film; and
removing the spacer layer from the sacrificial layer pattern and the interlayer dielectric film while leaving the spacer layer on the upper part of the first section of the metal layer.

6. The method of claim 1, wherein the forming of the spacer pattern comprises:
forming a blanket spacer layer on the substrate to such a thickness as to fill what remains of the trench; and
planarizing the spacer layer to such an extent that the third section of the metal layer is exposed.

7. The method of claim 1, wherein the spacer pattern is formed of at least one material selected from the group consisting of a silicon oxide, a silicon nitride and a carbon-based material.

8. The method of claim 1, wherein the forming of the first gate metal layer comprises:
etching the first section of the metal layer until the top thereof is disposed at the same level as or above the level of the upper surface of the second section of the metal layer, and
subsequently removing the sacrificial layer pattern and the spacer pattern.

9. The method of claim 8, wherein the sacrificial layer pattern is formed of material comprising siloxane, and the sacrificial layer pattern and the spacer pattern are removed using an etching solution of alkyl ammonium hydroxide.

10. The method of claim 1, wherein the interlayer dielectric layer is formed so as to have at least one trench therein on one region of the substrate and at least one trench therein on another region of the substrate,
the metal layer is formed in each of the trenches, and
the first gate metal layer is formed at the lower part of each of the trenches; and
further comprising removing the first gate metal layer from each said trench on said one region of the substrate while leaving the first gate metal layer in each said trench on said another region of the substrate.

11. The method of claim 10, wherein said another region of the substrate is a PMOS region dedicated to accommodate PMOS transistors, and said one region of the substrate is an NMOS region dedicated to accommodate NMOS transistors.

12. The method of claim 1, further comprising forming a second gate metal layer that fills what remains of the trench

13. The method of claim 1, wherein the forming of the interlayer dielectric layer comprises:
forming a dummy gate pattern on the substrate,
forming dielectric material on the substrate on which the dummy gate pattern is disposed, and
subsequently removing the dummy gate pattern.

14. A method of manufacturing a semiconductor device, the method comprising:
providing a substrate;
forming an interlayer dielectric layer having at least one first trench therein on one region of the substrate and at least one second trench therein on another region on the substrate;
forming a mask layer that covers said another region of the substrate;
forming a metal layer in each said at least one first trench, wherein the metal layer has a first section extending along the sides of each said first trench and a second section extending along the bottom of each said first trench;
forming a sacrificial layer pattern that fills only a lower part of each said first trench and exposes an upper part of the first section of the metal layer in the first trench;
forming a spacer pattern covering the surface of the exposed upper part of the first section of the metal layer in each said first trench;
forming a first gate metal layer at the lower part of each said first trench by etching the metal layer using the sacrificial layer and spacer patterns together as an etch mask;
removing the mask layer; and
subsequently forming a second gate metal layer that fills what remains of each said first trench and that fills each said second trench.

15. The method of claim 14, wherein the at least one first trench comprises one trench having a first width and another trench having a second width different from the first width, and the first metal layer is formed so as to have the same height in the trenches having the first and second widths different from each other.

16. A method of manufacturing a semiconductor device, the method comprising:
forming an interlayer dielectric layer having first and second trenches therein on a substrate;
subsequently forming a metal layer on the substrate conforming to the underlying topography of an intermediate structure that includes the interlayer dielectric layer and the first and second trenches, whereby the metal layer extends along surfaces delimiting the sides and bottoms of the first and second trenches;
subsequently forming a sacrificial layer pattern on the substrate by a process that results in the filling of the first trench with sacrificial material to a first level and the filling of the second trench with sacrificial material to a second level below the first level, such that the sacrificial layer pattern formed of said sacrificial material exposes more of the metal layer in the second trench than in the first trench;
forming a spacer pattern that covers those parts of the metal layer exposed by the sacrificial layer pattern; and
forming a first gate metal layer at the lower part of each of the first and second trenches by etching the metal layer using the sacrificial layer and spacer patterns together as an etch mask.

17. The method of claim 16, wherein the forming of the sacrificial layer pattern comprises:
depositing sacrificial material comprising siloxane on the substrate to form a sacrificial layer that is thicker at the location of the first trench than at the location of the second trench, and
etching the sacrificial layer.

18. The method of claim 16, wherein the spacer pattern is formed of at least one material selected from the group consisting of a silicon oxide, a silicon nitride and a carbon-based material.

19. The method of claim 16, wherein the first trench is narrower than the second trench, and
the forming of the first gate metal layer comprises etching the metal layer until the top thereof is disposed at the same level in each of the first and second trenches, and subsequently removing the sacrificial layer and spacer patterns; and
further comprising filling what remains of the first and second trenches with a second gate metal layer.

20. The method of claim 16, wherein the spacer pattern is formed of at least one material selected from the group consisting of a silicon oxide, a silicon nitride and a carbon-based material, the sacrificial layer pattern is formed of material comprising siloxane, and the sacrificial layer and spacer patterns are removed using an etching solution of alkyl ammonium hydroxide.
